(19) United States
(12) Patent Application Publication
(10) Pub. No.: US 2016/0086778 A1
(43) Pub. Date: Mar. 24, 2016

(54) SPUTTERING TARGET AND METHOD FOR MANUFACTURING TRANSPARENT CONDUCTIVE FILM USING THE SAME

(71) Applicant: Samsung Display Co., LTD., Yongin-City (KR)

(72) Inventors: Gun Hee KIM, Asan-si (KR); Woo Yong SONG, Seongnam-si (KR); Hoo Wan KANG, Asan-si (KR); Myun Joon PARK, (KR); Sung Baik AN, Hwaseong-si (KR); Ki Ryoung HAN, Seongnam-si (KR)

(21) Appl. No.: 14/713,542

(22) Filed: May 15, 2015

(30) Foreign Application Priority Data
Sep. 19, 2014 (KR) 10-2014-0124712

(51) Int. Cl. H01J 37/34; C23C 14/35; C23C 14/08

(52) U.S. Cl. CPC H01J 37/3429; C23C 14/086; C23C 14/35; H01J 37/3405; H01J 2237/3323

(57) ABSTRACT

A sputtering target includes: a first crystal comprising In₂O₃ in a bixbyite structure and SnO₂ of a tetragonal structure; and a second crystal comprising In₄Sn₃O₁₂ in an orthorhombic structure, wherein the second crystal accounts for 8 to 16% of a total size of the first and second crystals.

### CLAIM OF PRIORITY

This application claims the priority to and all the benefits accruing under 35 U.S.C. §119 of Korean Patent Application No. 10-2014-0124712, filed on Sep. 19, 2014, with the Korean Intellectual Property Office (“KIPO”), the disclosure of which is incorporated herein in its entirety by reference.

### BACKGROUND OF THE INVENTION

1. Field of the Invention

Aspects of embodiments of the present invention relate to a sputtering target capable of manufacturing a transparent conductive layer having uniform thickness and crystallization and to a method of manufacturing a transparent conductive layer using the sputtering target.

2. Description of the Related Art

Transparent conductive layers are applied in electrodes or wirings of a variety display devices, such as a liquid crystal display (LCD) and an organic light emitting diode (OLED), by virtue of characteristics of high conductivity and excellent visible light transmittance.

The transparent conductive layer is manufactured by performing sputtering of a sputtering target, and therefore characteristics of the sputtering target may directly affect characteristics of the transparent conductive layer. A currently most widely used sputtering target is formed of indium-tin-oxide (ITO). An ITO layer is formed to have excellent conductivity and transparency using this ITO. However, impurities originating from the sputtering process, i.e. SiO₂ or Al₂O₃ particles, could be collected on the target material and act as nucleus in nodule formation process. Nodules, also called “black growths” or black crystals”, in the form of conical defects formed on the surface of the target material can reduce sputtering voltage and efficiency, and affect crystallization and target life of the sputtering target and thin film qualities as uniform thickness and electrical properties of transparent conductive layer formed during sputtering using the sputtering target. Also, the sputtering target could have large brittleness and be easily broken during handling for sputtering process, affecting the thin film qualities of the formed transparent conductive layers.

It is to be understood that this background of the technology section is intended to provide useful background for understanding the technology and as such disclosed herein, the technology background section may include ideas, concepts or recognitions that were not part of what was known or appreciated by those skilled in the pertinent art prior to a corresponding effective filing date of subject matter disclosed herein.

### SUMMARY OF THE INVENTION

The present disclosure of invention is directed to a sputtering target capable of manufacturing a transparent conductive layer having uniform thickness and crystallization and improved in target life and to a method of manufacturing a transparent conductive layer using the sputtering target.

According to an embodiment of the present invention, a sputtering target includes: a first crystal comprising In₂O₃ in a bixbyite structure and SnO₂ in a tetragonal structure; and a second crystal comprising In₄Sn₃O₁₂ in an orthorhombic structure. The second crystal may account for 8 to 16% of a total size of the first and second crystals.

The first crystal may include 85 to 95 wt % In₂O₃ and 5 to 15 wt % of SnO₂.

The first crystal may include 90 wt % of In₂O₃ and 10 wt % of SnO₂.

The second crystal may include In₄Sn₃O₁₂ that comprises 38 to 46 wt % of Sn based on 100 wt % of a total weight of In and Sn.

The second crystal may include In₄Sn₃O₁₂ that comprises 42 wt % of Sn based on 100 wt % of a total weight of In and Sn.

The second crystal may have an average crystal size of 2 to 4 μm².

The second crystal may account for 8.8 to 15.2% of a total size of the first and second crystals.

According to an embodiment of the present invention, a method of manufacturing a transparent conductive layer includes: performing deposition of a transparent conductive layer by performing sputtering of the sputtering target; and performing heat treatment of the transparent conductive layer.

The deposition may be performed at a temperature of 50 to 150 degrees.

The heat treatment may be performed at a temperature of 150 to 250 degrees.

According to embodiments of the present invention, nodules that are formed on a surface when performing sputtering are reduced, thereby capable of manufacturing a transparent conductive layer having uniform thickness and crystallization.

Further, according to embodiments of the present invention, target life of the sputtering target may be increased, thereby improving manufacturing efficiency of the transparent conductive layer.

The foregoing is illustrative only and is not intended to be in any way limiting. In addition to the illustrative aspects, embodiments, and features described above, further aspects, embodiments, and features will become apparent by reference to the drawings and the following

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings, in which like reference symbols indicate the same or similar components, wherein:

FIG. 1 is an SEM image taken with a scanning electron microscope (SEM) illustrating a sputtering target according to an embodiment of the present invention;

FIG. 2 is an SEM image illustrating a sputtering target according to another embodiment of the present invention;

FIG. 3 is an SEM image illustrating a sputtering target according to yet another embodiment of the present invention;

FIG. 4 is an SEM image illustrating a sputtering target according to yet another embodiment of the present invention;

FIG. 5 is a graph illustrating thickness and lower erosion length of a transparent conductive layer according to exemplary embodiments 1 to 4 and comparative example 1;

FIG. 6 is a graph illustrating crystal size and crystallization of the transparent conductive layer according to the exemplary embodiments 1 to 4 and comparative example 1; and

FIG. 7 is a graph illustrating a sheet resistance Rs according to an amount of power consumption of the transparent conductive layer according to the exemplary embodiment 2 and comparative example 1.

FIG. 8 shows formation of a layer on nodules due to self-sputtering target surface.

### DETAILED DESCRIPTION OF THE INVENTION

Advantages and features of the present invention and methods for achieving them will be made clear from embodiments described below in detail with reference to the accompanying drawings. The present invention may, however, be embodied in many different forms and should not be construed as being limited to the embodiments set forth herein. Rather, these embodiments are provided so that this disclosure will be thorough and complete, and will fully convey the scope of the invention to those skilled in the art. The present invention is merely defined by the scope of the claims. Therefore, well-known constituent elements, operations and techniques are not described in detail in the embodiments in order to prevent the present invention from being obscurely interpreted. Like reference numerals refer to like elements throughout the specification.

The spatially relative terms “below”, “beneath”, “lower”, “above”, “upper”, and the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device shown in the drawing is turned over, the device positioned “below” or “beneath” another device may be placed “above” another device. Accordingly, the illustrative term “below” may include both the lower and upper positions. The device may also be oriented in the other direction, and thus the spatially relative terms may be interpreted differently depending on the orientations.

Throughout the specification, when an element is referred to as being “connected” to another element, the element is “directly connected” to the other element, or “electrically connected” to the other element with one or more intervening elements interposed therebetween. It will be further understood that the terms “comprises,” “comprising,” “includes” and/or “including,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms used herein (including technical and scientific terms) have the same meaning as commonly understood by those skilled in the art to which this invention pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the present specification.

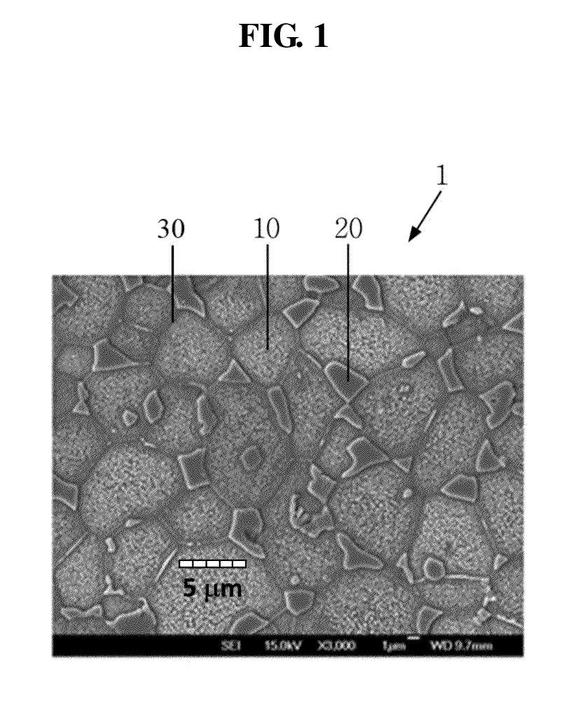

Referring to FIGS. 1 to 4, a sputtering target 1 according to an embodiment of the present invention may include a first crystal 10 and a second crystal 20. The grain boundary 30 is formed between the crystals.

The first crystal 10 may include In₂O₃ in a bixbyite structure and SnO₂ in a tetragonal structure. In more detail, the first crystal 10 may include 90 wt % of In₂O₃ and 10 wt % of SnO₂, but is not limited thereto. In some embodiments, the first crystal 10 may include 85 to 95 wt % of In₂O₃ and 5 to 15 wt % of SnO₂.

The second crystal 20 may include In₄Sn₃O₁₂ in an orthorhombic structure. In more detail, the second crystal 20 may include In₄Sn₃O₁₂ including 42 wt % of Sn based on 100 wt % of a total weight of In and Sn, but is not limited thereto. In some embodiments, the second crystal 20 may include In₄Sn₃O₁₂ including 38 to 46 wt % of Sn based on 100 wt % of a total weight of In and Sn.

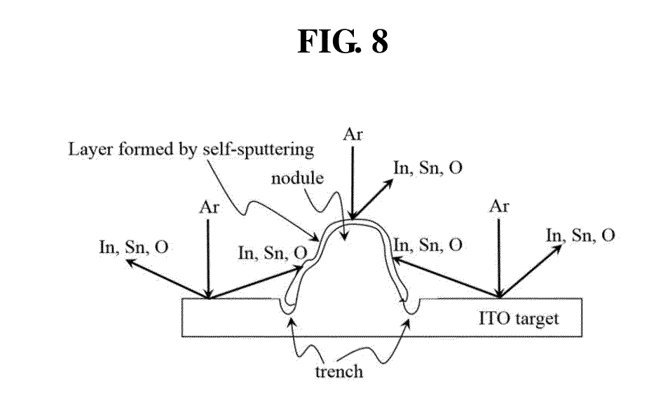

The second crystal 20 may account for about 8 to 16% of a total size of the first and second crystals 10 and 20. When the second crystal 20 has a size less than 8% of a total size of the first and second crystals 10 and 20, the sputtering target 1 may have a disadvantage in manufacturing a transparent conductive layer having high conductivity and visible light transmittance. Further, when the second crystal 20 has a size more than 16% of a total size of the first and second crystals 10 and 20, roughness of the sputtering target 1 is increased and nodules formed on a surface of the sputtering target 1 are increased when performing sputtering, which makes it hard to manufacture a transparent conductive layer having uniform thickness and crystallization. In more detail, the first crystal 10 has a higher hardness than the second crystal 20 and the second crystal 20 is more quickly sputtered than the first crystal 10. Accordingly, the roughness of the sputtering target 1 is increased and nodules may be produced due to self-sputtering sputtering occurring at the surface of the sputtering target 1 when performing sputtering. FIG. 8 shows that the nodules could lead to a consequence of a layer formed due to self-sputtering of the sputtering target 1 and the particles ejected from this layer during sputtering would have less oxygen concentration and trench formation.

The second crystal 20 may have an average crystal size of about 2 to 4 μm². When the second crystal 20 has an average crystal size of less than 2 μm², pores between the first and second crystals 10 and 20 may be increased in number, such that the sputtering target 1 may have a disadvantageously large brittleness and be easily broken. Further, when the second crystal 20 has an average crystal size of larger than 4 μm², roughness of the sputtering target 1 is increased and thus nodules formed on a surface of the sputtering target 1 are increased when performing sputtering. Accordingly, the sputtering target 1 may have a disadvantage in manufacturing a transparent conductive layer having uniform thickness and crystallization.

Referring to an SEM image of FIG. 1, a sputtering target 1 according to one embodiment of the present invention may include a first crystal 10 that may account for 84.8% and a second crystal 20 that may account for 15.2% of a total size of the first and second crystals 10 and 20.

The second crystal 20 may have a maximum crystal size of 8.1 μm², a minimum crystal size of 0.8 μm², and an average crystal size of 3.5 μm².

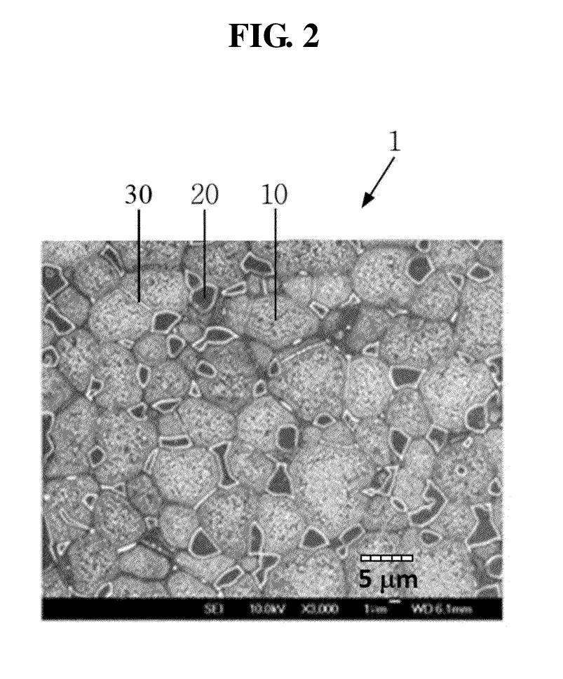

Referring to an SEM image of FIG. 2, a sputtering target 1 according to another embodiment of the present invention may include a first crystal 10 that may account for 85.2% and a second crystal 20 that may account for 14.8% of a total size of the first and second crystals 10 and 20. The grain boundary 30 is formed between the crystals.

The second crystal 20 may have a maximum crystal size of 8.8 μm², a minimum crystal size of 0.4 μm², and an average crystal size of 2.8 μm².

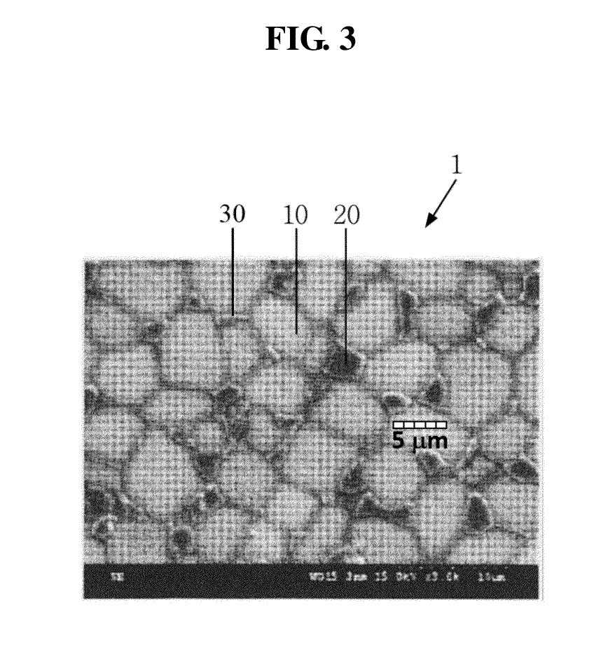

Referring to an SEM image of FIG. 3, a sputtering target 1 according to another embodiment of the present invention may include a first crystal 10 that may account for 86.1% and a second crystal 20 that may account for 13.9% of a total size of the first and second crystals 10 and 20. The grain boundary 30 is formed between the crystals.

The second crystal 20 may have a maximum crystal size of 8.5 μm², a minimum crystal size of 0.6 μm², and an average crystal size of 3.2 μm².

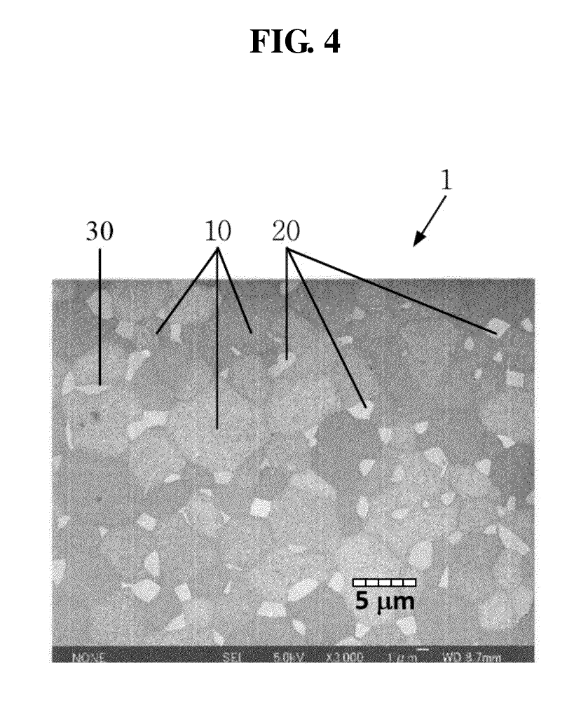

Referring to an SEM image of FIG. 4, a sputtering target 1 according to yet another embodiment of the present invention may include a first crystal 10 that may account for 91.2% and a second crystal 20 that may account for 8.8% of a total size of the first and second crystals 10 and 20. The grain boundary 30 is formed between the crystals.

The second crystal 20 may have a maximum crystal size of 7.8 μm², a minimum crystal size of 0.5 μm², and an average crystal size of 2.19 μm².

Hereinafter, a transparent conductive layer manufactured by the sputtering target according to an embodiment of the present invention will be described along with exemplary embodiments and comparative examples.

### Exemplary Embodiment 1

A sputtering target used to manufacture a transparent conductive layer according to an exemplary embodiment 1 may include a first crystal including 90 wt % of In₂O₃ and 10 wt % of SnO₂ and a second crystal including In₄Sn₃O₁₂ that may include 42 wt % of Sn based on 100 wt % of a total weight of In and Sn. In this case, the second crystal may account for 15.2% of a total size of the first and second crystals and have an average crystal size of 3.5 μm².

The sputtering target that has consumed power of 300 kWh is equipped on a DC magnetron sputtering device, 190 sccm of argon (Ar) and 8 sccm of oxygen (O₂) are then injected in a chamber, and then a transparent conductive layer is deposited on a substrate under the condition of temperature of 130° C. and pressure of 0.7 Pa. Subsequently, the transparent conductive layer is subject to heat treatment for 30 minutes at a temperature of 230° C. in an oven to manufacture a first transparent conductive layer. However, embodiments of the present invention are not limited thereto. In some embodiments, the deposition may be performed at a temperature of 50 to 150° C. and the heat treatment may be performed at a temperature of 150 to 250° C. depending on an external condition.

Further, a sputtering target that has consumed power of 1700 kWh is subject to sputtering in the method described above to manufacture a second transparent conductive layer.

The first transparent conductive layer is measured to be 1500 Å in thickness, 271 nm in lower erosion length, 0.403 arcsec in crystallization, and 195 Å in crystal size. Herein, the lower erosion length refers to a loosening-off length of a transparent conductive layer deposited on a substrate.

The second transparent conductive layer is measured to be 1395 Å in thickness, 400 nm in lower erosion length, 0.457 arcsec in crystallization, and 178 Å in crystal size.

Characteristics of the first and second transparent conductive layers according to the exemplary embodiment 1 are shown in Table 1.

### Exemplary Embodiment 2

A sputtering target used to manufacture a transparent conductive layer according to an exemplary embodiment 2 may include a first crystal including 90 wt % of In₂O₃ and 10 wt % of SnO₂ and a second crystal including In₄Sn₃O₁₂ that may include 42 wt % of Sn based on 100 wt % of a total weight of In and Sn. In this case, the second crystal may account for 14.8% of a total size of the first and second crystals and may have an average crystal size of 2.8 μm².

A sputtering target consumed power of 300 kWh is subject to sputtering in a method as in the exemplary embodiment 1 to manufacture a third transparent conductive layer.

A sputtering target consumed power of 2000 kWh is subject to sputtering in a method as in the exemplary embodiment 1 to manufacture a fourth transparent conductive layer.

The third transparent conductive layer is measured to be 1500 Å in thickness, 271 nm in lower erosion length, 0.403 arcsec in crystallization, and 195 Å in crystal size.

The fourth transparent conductive layer is measured to be 1420 Å in thickness, 313 nm in lower erosion length, 0.426 arcsec in crystallization, and 188 Å in crystal size.

Characteristics of the second and third transparent conductive layers according to the exemplary embodiment 2 are shown in Table 1.

### Exemplary Embodiment 3

A sputtering target used to manufacture a transparent conductive layer according to an exemplary embodiment 3 may include a first crystal including 90 wt % of In₂O₃ and 10 wt % of SnO₂ and a second crystal including In₄Sn₃O₁₂ that may include 42 wt % of Sn based on 100 wt % of a total weight of In and Sn. In this case, the second crystal may account for 13.9% of a total size of the first and second crystals and may have an average crystal size of 3.2 μm².

A sputtering target that has consumed power of 300 kWh is subject to sputtering in a method as in the exemplary embodiment 1 to manufacture a fifth transparent conductive layer.

A sputtering target that has consumed power of 2000 kWh is subject to sputtering in a method as in the exemplary embodiment 1 to manufacture a sixth transparent conductive layer.

The fifth transparent conductive layer is measured to be 1500 Å in thickness, 271 nm in lower erosion length, 0.403 arcsec in crystallization, and 195 Å in crystal size.

The sixth transparent conductive layer is measured to be 1432 Å in thickness, 306 nm in lower erosion length, 0.413 arcsec in crystallization, and 191 Å in crystal size.

Characteristics of the fifth and sixth transparent conductive layers according to the exemplary embodiment 3 are shown in Table 1.

### Exemplary Embodiment 4

A sputtering target used to manufacture a transparent conductive layer according to an exemplary embodiment 4 may include a first crystal including 90 wt % of In₂O₃ and 10 wt % of SnO₂ and a second crystal including In₄Sn₃O₁₂ that may include 42 wt % of Sn based on 100 wt % of a total weight of In and Sn. In this case, the second crystal may account for 8.8% of a total size of the first and second crystals and may have an average crystal size of 2.19 μm².

A sputtering target that has consumed power of 300 kWh is subject to sputtering in a method as in the exemplary embodiment 1 to manufacture a seventh transparent conductive layer.

A sputtering target that has consumed power of 2000 kWh is subject to sputtering in a method as in the exemplary embodiment 1 to manufacture an eighth transparent conductive layer.

The seventh transparent conductive layer is measured to be 1500 Å in thickness, 271 nm in lower erosion length, 0.403 arcsec in crystallization, and 195 Å in crystal size.

The eighth transparent conductive layer is measured to be 1415 Å in thickness, 327 nm in lower erosion length, 0.432 arcsec in crystallization, and 184 Å in crystal size.

Characteristics of the seventh and eighth transparent conductive layers according to the exemplary embodiment 4 are shown in Table 1.

### COMPARATIVE EXAMPLE 1

A sputtering target used to manufacture a transparent conductive layer according to a comparative example 1 may include a first crystal including 90 wt % of In₂O₃ and 10 wt % of SnO₂ and a second crystal including In₄Sn₃O₁₂ that may include 42 wt % of Sn based on 100 wt % of a total weight of In and Sn. In this case, the second crystal may account for 18.0% of a total size of the first and second crystals and may have an average crystal size of 6.0 μm².

A sputtering target that has consumed power of 300 kWh is subject to sputtering in a method as in the exemplary embodiment 1 to manufacture a ninth transparent conductive layer.

A sputtering target that has consumed power of 1700 kWh is subject to sputtering in a method as in the exemplary embodiment 1 to manufacture a tenth transparent conductive layer.

The ninth transparent conductive layer is measured to be 1500 Å in thickness, 271 nm in lower erosion length, 0.403 arcsec in crystallization, and 195 Å in crystal size.

The tenth transparent conductive layer is measured to be 1388 Å in thickness, 425 nm in lower erosion length, 0.499 arcsec in crystallization, and 166 Å in crystal size.

Characteristics of the ninth and tenth transparent conductive layers according to the comparative example 1 are shown in Table 1.

TABLE 1

| | Exemplary | | Exemplary | | Exemplary | | Exemplary | | Comparative | |
|---|---|---|---|---|---|---|---|---|---|---|
| | embodiment 1 | | embodiment 2 | | embodiment 3 | | embodiment 4 | | Example 1 | |
| | Transparent conductive layer | | | | | | | | | |
| | 1 | 2 | 3 | 4 | 5 | 6 | 7 | 8 | 9 | 10 |
| Power | 300 | 1700 | 300 | 2000 | 300 | 2000 | 300 | 2000 | 300 | 1700 |
| consumption | | | | | | | | | | |
| (kWh) | | | | | | | | | | |
| Thickness | 1500 | 1395 | 1500 | 1420 | 1500 | 1432 | 1500 | 1415 | 1500 | 1388 |
| (Å) | | | | | | | | | | |
| Lower erosion | 271 | 400 | 271 | 313 | 271 | 306 | 271 | 327 | 271 | 425 |
| length | | | | | | | | | | |
| (nm) | | | | | | | | | | |
| Crystallization | 0.403 | 0.457 | 0.403 | 0.426 | 0.403 | 0.413 | 0.403 | 0.432 | 0.403 | 0.499 |
| (arcsec) | | | | | | | | | | |
| Crystal size | 195 | 178 | 195 | 188 | 195 | 191 | 195 | 184 | 195 | 166 |
| (Å) | | | | | | | | | | |

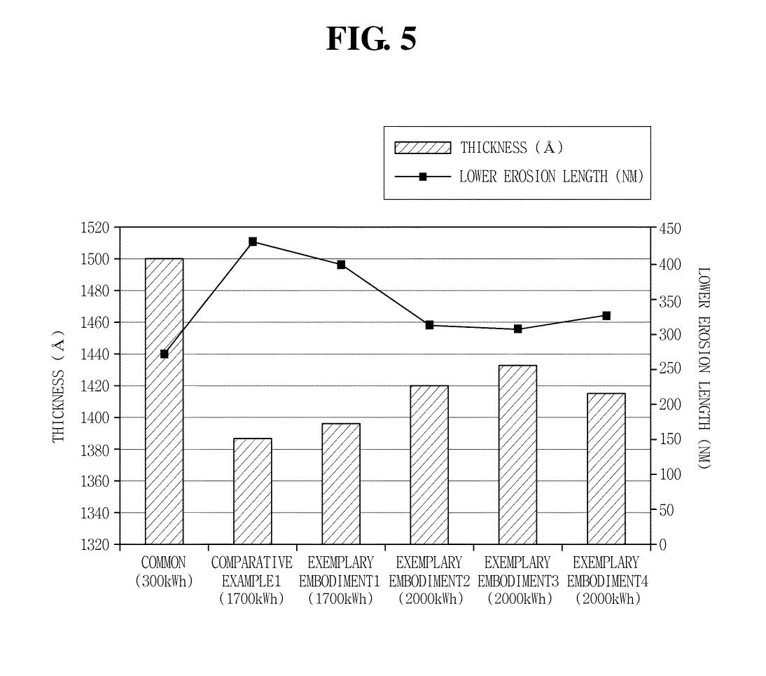

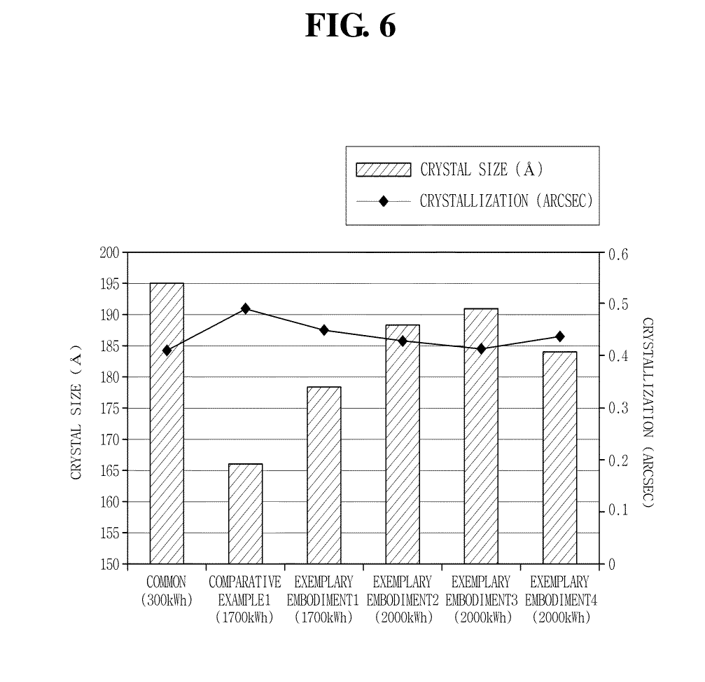

Referring to Table 1 and FIGS. 5 and 6, the first, third, fifth, seventh, and ninth transparent conductive layers according to the exemplary embodiments 1, 2, 3, and 4 and comparative example 1 that are manufactured by performing sputtering on the respective sputtering targets that have consumed 300 kWh of power, that is, at an early stage of target life, exhibit identical properties.

However, the second, fourth, sixth, eighth, and tenth transparent conductive layers of the exemplary embodiments 1, 2, 3, and 4 and comparative example 1 that are manufactured by performing sputtering on the respective sputtering targets that have consumed 1700 kWh or 2000 kWh of power, that is, at a late stage of target life, exhibit properties different from each other.

That is, the transparent conductive layers of the exemplary embodiments 1 to 4 exhibit a small difference in properties between the early and late stages of target life of the sputtering target, whereas the transparent conductive layer of the comparative example 1 exhibits a considerably large difference in properties between the early and late stages of target life of the sputtering target. This suggests that the size of the second crystal composing the sputtering target may affect characteristics of the transparent conductive layer and target life.

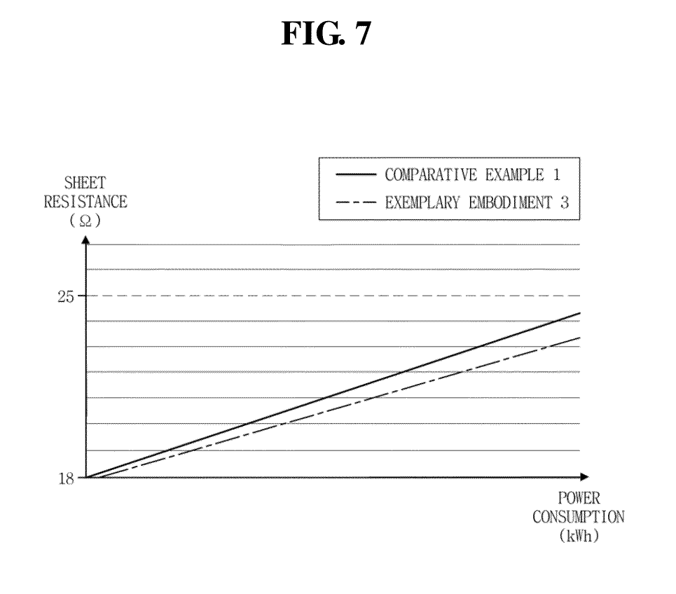

Referring to FIG. 7, the transparent conductive layer according to the exemplary embodiment 2 may show a lower sheet resistance and a lower sheet resistance increase range according to power consumption compared to the transparent conductive layer according to the comparative example 1. This suggests that the size of the second crystal composing the sputtering target may affect the sheet resistance Rs of the transparent conductive layer.

From the foregoing, it will be appreciated that various embodiments in accordance with the present disclosure have been described herein for purposes of illustration, and that various modifications may be made without departing from the scope and spirit of the present teachings. Accordingly, the various embodiments disclosed herein are not intended to be limiting of the true scope and spirit of the present teachings.

What is claimed is:

1. A sputtering target comprising:
a first crystal comprising In₂O₃ in a bixbyite structure and SnO₂ in a tetragonal structure; and
a second crystal comprising In₄Sn₃O₁₂ in an orthorhombic structure,
wherein the second crystal accounts for 8 to 16% of a total size of the first and second crystals.

2. The sputtering target of claim 1, wherein the first crystal comprises 85 to 95 wt % of In₂O₃ and 5 to 15 wt % of SnO_{2.}

3. The sputtering target of claim 2, wherein the first crystal comprises 90 wt % of In₂O₃ and 10 wt % of SnO_{2.}

4. The sputtering target of claim 1, wherein the second crystal comprises In₄Sn₃O₁₂ that comprises 38 to 46 wt % of Sn based on 100 wt % of a total weight of In and Sn.

5. The sputtering target of claim 4, wherein the second crystal comprises In₄Sn₃O₁₂ that comprises 42 wt % of Sn based on 100 wt % of a total weight of In and Sn.

6. The sputtering target of claim 1, wherein the second crystal has an average crystal size of 2 to 4 μm².

7. The sputtering target of claim 1, wherein the second crystal accounts for 8.8 to 15.2% of a total size of the first and second crystals.

8. A method of manufacturing a transparent conductive layer, the method comprising:
performing deposition of a transparent conductive layer by performing sputtering of the sputtering target of one of claims 1 to 7; and
performing heat treatment of the transparent conductive layer.

9. The method of claim 8, wherein the deposition is performed at a temperature of 50 to 150 degrees.

10. The method of claim 8, wherein the heat treatment is performed at a temperature of 150 to 250 degrees.
